(19) United States
(12) Patent Application Publication
(10) Pub. No.: US 2023/0055258 A1
(43) Pub. Date: Feb. 23, 2023

(54) FORMATION OF AN EPITAXIAL BARRIER BETWEEN A SEMICONDUCTOR SUBSTRATE AND A METAL RESONATOR FOR IMPROVED SUBSTRATE METAL PARTICIPATION

(71) Applicant: International Business Machines Corporation, Armonk, NY (US)

(72) Inventor: Kenneth P. Rodbell, Sandy Hook, CT (US)

(21) Appl. No.: 17/445,263

(22) Filed: Aug. 17, 2021

(51) Int. Cl. H01L 39/24; H01L 39/12; H01L 39/22

(52) U.S. Cl. CPC H01L 39/2406; H01L 39/12; H01L 39/223

(57) ABSTRACT

A method comprising cleaning the top surface of a silicon substrate and forming a diffusion barrier by depositing a metal on top the top surface of the silicon substrate. The diffusion barrier is formed one monolayer at a time and wherein the diffusion barrier will have a height of about 1 to 3 nm. Forming a layer of crystalline Niobium on top of the diffusion barrier.

### STATEMENT REGARDING FEDERALLY FUNDED RESEARCH AND DEVELOPMENT

This invention was made with U.S. Government support. The U.S. Government has certain rights in this invention.

### BACKGROUND

The present invention relates generally to the field of semiconductor devices, and more particularly to epitaxial forming an intermediate layer for a crystalline superconductor to be formed on.

When forming a superconductor layer on top of substrate, the superconductor and the substrate can inter-diffuse between each other to form an intermetallic film between the substrate and the superconductor layer. This intermetallic film can be an amorphous layer which can cause defects in the superconductor layer.

### BRIEF SUMMARY

Additional aspects and/or advantages will be set forth in part in the description which follows and, in part, will be apparent from the description, or may be learned by practice of the invention.

A method comprising cleaning the top surface of a silicon substrate and forming a diffusion barrier by depositing a metal on top the top surface of the silicon substrate. The diffusion barrier is formed one monolayer at a time and wherein the diffusion barrier will have a height of about 1 to 3 nm. Forming a layer of crystalline Niobium on top of the diffusion barrier.

Wherein the metal is selected from a group consisting of: aluminum, cobalt, gallium, indium, lanthanum, molybdenum, niobium, rhenium, ruthenium, tin, tantalum, titanium, zinc, zirconium, and alloys thereof.

Wherein the diffusion barrier is a silicide alloy comprised of the deposited metal and the silicon wafer.

Wherein the silicide alloy is selected from a group consisting of: CoSi₂, NbSi₂, TiSi₂.

A resonator comprising a silicon wafer, and a diffusion barrier formed on the surface of the silicon wafer. Wherein the diffusion barrier by depositing a metal on top the top surface of the silicon substrate. The diffusion barrier is formed one monolayer at a time, and wherein the diffusion barrier will have a height of about 1 to 3 nm. A crystalline niobium resonator formed on top of the diffusion barrier.

A device comprising a silicon wafer and a diffusion barrier formed on the surface of the silicon wafer. The diffusion barrier by depositing a metal on top the top surface of the silicon substrate, and wherein the diffusion barrier is formed one monolayer at a time. The diffusion barrier will have a height of about 1 to 3 nm. A first crystalline niobium layer formed on top of the diffusion barrier and a tunnel barrier material formed on top of the first crystalline niobium layer. A second crystalline niobium layer formed on top of the tunnel barrier material.

### BRIEF DESCRIPTION OF THE DRAWINGS

The above and other aspects, features, and advantages of certain exemplary embodiments of the present invention will be more apparent from the following description taken in conjunction with the accompanying drawings, in which:

FIG. 1 illustrates an initial stage of fabrication of a product, in accordance with an embodiment of the present invention.

FIG. 2 illustrates a diffusion barrier that was epitaxially grown on the substrate, in accordance with an embodiment of the present invention.

FIG. 3 illustrates a layer formed on the diffusion barrier, in accordance with an embodiment of the present invention.

FIG. 4 illustrates the product after the layer and the diffusion barrier were etched, in accordance with an embodiment of the present invention.

FIG. 5 illustrates a plurality of layers formed above the diffusion barrier, in accordance with an embodiment of the present invention.

FIG. 6 illustrates the product after the plurality of layers and the diffusion barrier were etched, in accordance with an embodiment of the present invention.

### DETAILED DESCRIPTION

The following description with reference to the accompanying drawings is provided to assist in a comprehensive understanding of exemplary embodiments of the invention as defined by the claims and their equivalents. It includes various specific details to assist in that understanding but these are to be regarded as merely exemplary. Accordingly, those of ordinary skill in the art will recognize that various changes and modifications of the embodiments described herein can be made without departing from the scope and spirit of the invention. In addition, descriptions of well-known functions and constructions may be omitted for clarity and conciseness.

The terms and words used in the following description and claims are not limited to the bibliographical meanings, but, are merely used to enable a clear and consistent understanding of the invention. Accordingly, it should be apparent to those skilled in the art that the following description of exemplary embodiments of the present invention is provided for illustration purpose only and not for the purpose of limiting the invention as defined by the appended claims and their equivalents.

It is to be understood that the singular forms “a,” “an,” and “the” include plural referents unless the context clearly dictates otherwise. Thus, for example, reference to “a component surface” includes reference to one or more of such surfaces unless the context clearly dictates otherwise.

Detailed embodiments of the claimed structures and methods are disclosed herein; however, it can be understood that the disclosed embodiments are merely illustrative of the claimed structures and methods that may be embodied in various forms. This invention may, however, be embodied in many different forms and should not be construed as limited to the exemplary embodiments set forth herein. Rather, these exemplary embodiments are provided so that this disclosure will be thorough and complete and will fully convey the scope of this invention to those skilled in the art. In the description, details of well-known features and techniques may be omitted to avoid unnecessarily obscuring the presented embodiments.

References in the specification to “one embodiment”, “an embodiment”, “an example embodiment”, etc., indicate that the embodiment described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

For purposes of the description hereinafter, the terms “upper”, “lower”, “right”, “left”, “vertical”, “horizontal”, “top”, “bottom”, and derivatives thereof shall relate to the disclosed structures and methods, as oriented in the drawing figures. The terms “overlying”, “atop”, “on top”, “positioned on” or “positioned atop” mean that a first element, such as a first structure, is present on a second element, such as a second structure, wherein intervening elements, such as an interface structure may be present between the first element and the second element. The term “direct contact” means that a first element, such as a first structure, and a second element, such as a second structure, are connected without any intermediary conducting, insulating or semiconductor layers at the interface of the two elements.

In the interest of not obscuring the presentation of embodiments of the present invention, in the following detailed description, some processing steps or operations that are known in the art may have been combined together for presentation and for illustration purposes and in some instances may have not been described in detail. In other instances, some processing steps or operations that are known in the art may not be described at all. It should be understood that the following description is rather focused on the distinctive features or elements of various embodiments of the present invention.

Various embodiments of the present invention are described herein with reference to the related drawings. Alternative embodiments can be devised without departing from the scope of this invention. It is noted that various connections and positional relationships (e.g., over, below, adjacent, etc.) are set forth between elements in the following description and in the drawings. These connections and/or positional relationships, unless specified otherwise, can be direct or indirect, and the present invention is not intended to be limiting in this respect. Accordingly, a coupling of entities can refer to either a direct or an indirect coupling, and a positional relationship between entities can be a direct or indirect positional relationship. As an example of an indirect positional relationship, references in the present description to forming layer “A” over layer “B” include situations in which one or more intermediate layers (e.g., layer “C”) is between layer “A” and layer “B” as long as the relevant characteristics and functionalities of layer “A” and layer “B” are not substantially changed by the intermediate layer(s).

The following definitions and abbreviations are to be used for the interpretation of the claims and the specification. As used herein, the terms “comprises,” “comprising,” “includes,” “including,” “has,” “having,” “contains” or “containing,” or any other variation thereof, are intended to cover a non-exclusive inclusion. For example, a composition, a mixture, process, method, article, or apparatus that comprises a list of elements is not necessarily limited to only those elements but can include other elements not expressly listed or inherent to such composition, mixture, process, method, article, or apparatus.

Additionally, the term “exemplary” is used herein to mean “serving as an example, instance or illustration.” Any embodiment or design described herein as “exemplary” is not necessarily to be construed as preferred or advantageous over other embodiments or designs. The terms “at least one” and “one or more” can be understood to include any integer number greater than or equal to one, i.e. one, two, three, four, etc. The terms “a plurality” can be understood to include any integer number greater than or equal to two, i.e. two, three, four, five, etc. The term “connection” can include both an indirect “connection” and a direct “connection.”

As used herein, the term “about” modifying the quantity of an ingredient, component, or reactant of the invention employed refers to variation in the numerical quantity that can occur, for example, through typical measuring and liquid handling procedures used for making concentrates or solutions. Furthermore, variation can occur from inadvertent error in measuring procedures, differences in the manufacture, source, or purity of the ingredients employed to make the compositions or carry out the methods, and the like. The terms “about” or “substantially” are intended to include the degree of error associated with measurement of the particular quantity based upon the equipment available at the time of filing application. For example, “about” can include a range of ±8% or 5%, or 2% of a given value. In one aspect, the term “about” means within 10% of the reported numerical value. In another aspect, the term “about” means within 5% of the reported numerical value. Yet, in another aspect, the term “about” means within 10, 9, 8, 7, 6, 5, 4, 3, 2, or 1% of the reported numerical value. The terms “about” or “substantially” are intended to include the degree of error associated with measurement of the particular quantity based upon the equipment available at the time of filing application.

Various processes used to form a micro-chip that will be packaged into an integrated circuit (IC) fall into four general categories, namely, film deposition, removal/etching, semiconductor doping and patterning/lithography. Deposition is any process that grows, coats, or otherwise transfers a material onto the wafer. Available technologies include physical vapor deposition (PVD), chemical vapor deposition (CVD), electrochemical deposition (ECD), molecular beam epitaxy (MBE) and more recently, atomic layer deposition (ALD) among others. Removal/etching is any process that removes material from the wafer. Examples include etch processes (either wet or dry), and chemical-mechanical planarization (CMP), and the like. Semiconductor doping is the modification of electrical properties by doping, for example, transistor sources and drains, generally by diffusion and/or by ion implantation. These doping processes are followed by furnace annealing or by rapid thermal annealing (RTA). Annealing serves to activate the implanted dopants. Films of both conductors (e.g., poly-silicon, aluminum, copper, etc.) and insulators (e.g., various forms of silicon dioxide, silicon nitride, etc.) are used to connect and isolate transistors and their components. Selective doping of various regions of the semiconductor substrate allows the conductivity of the substrate to be changed with the application of voltage. By creating structures of these various components, millions of transistors can be built and wired together to form the complex circuitry of a modern microelectronic device.

Reference will now be made in detail to the embodiments of the present invention, examples of which are illustrated in the accompanying drawings, wherein like reference numerals refer to like elements throughout. Embodiments of the invention are generally directed to epitaxially growing an intermediate layer between a superconducting layer and a crystalline silicon substrate. The crystalline silicon substrate has a crystalline lattice structure with a corresponding lattice constant, i.e. d-spacing, which refers to the physical dimensions of the unit cells that make up the crystalline lattice. When forming, for example, a niobium resonator on a crystalline silicon substrate, the niobium and the silicon will interdiffuse with each other since the lattice constant (and crystallographic types and orientations) for the niobium and the silicon are not same. When the niobium is formed on top of the silicon an initial amorphous alloy of Nb and Si will form at the niobium-silicon interface, which transitions into a strained crystalline structure of Nb before the unstrained crystalline Nb is formed on top of the strained Nb. The interface of the two crystalline structure will be under stress, for example, tensile or compressive stress. When a film such as Nb is deposited onto Si any lattice mismatch between the two will result in a stress to develop depending on the deposition conditions, the deposition temperature and the thickness of both the thin film (Nb) and the substrate (Si). This is typically captured in the Stoney equation. Alternatively, the thin film atoms (for example, Nb) and the substrate (for example, Si) can intermix locally (at the interface) forming an alloy. This alloy is typically amorphous, containing defects in both the niobium and Si lattice structures. To prevent this from occurring a diffusion barrier can be epitaxially grown on the surface of the silicon to prevent the niobium from diffusing into the silicion and forming such an alloy. By epitaxially growing a suitable diffusion barrier one layer at a time, the difference in the lattice constants of Nb and Si can be addressed by providing a buffer layer between the two that can gradually shift from that of the substrate Si to that of the thin film Nb.

Examples of various epitaxial growth process apparatuses that may be suitable for use in forming the crystalline diffusion barrier may include, for example, molecular beam epitaxy (MBE), rapid thermal chemical vapor deposition (RTCVD), low-energy plasma deposition (LEPD), ultra-high vacuum chemical vapor deposition (UHVCVD), atomic layer deposition (ALD) and atmospheric pressure chemical vapor deposition (APCVD).

The terms “epitaxial growth and/or deposition” and “epitaxially formed and/or grown” mean the growth of a semiconductor material on a deposition surface of a semiconductor material, in which the semiconductor material being grown has the same crystalline characteristics as the semiconductor material of the deposition surface. In an epitaxial deposition process, the chemical reactants provided by the source gases are controlled and the system parameters are set so that the depositing atoms arrive at the deposition surface of the semiconductor substrate with sufficient energy to move around on the surface and orient themselves to the crystal arrangement of the atoms of the deposition surface. Therefore, an epitaxial semiconductor material has the same crystalline characteristics as the deposition surface on which it is formed. For example, an epitaxial semiconductor material deposited on a {100} crystal surface will take on a {100} orientation. In some embodiments, epitaxial growth and/or deposition processes are selective to forming on semiconductor surface, and do not deposit material on dielectric surfaces, such as silicon dioxide or silicon nitride surfaces.

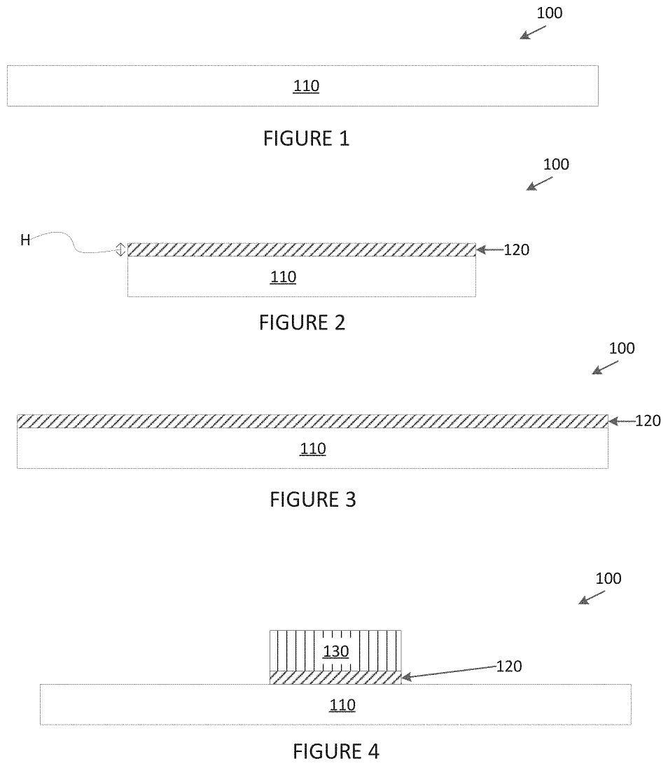

FIG. 1 illustrates an initial stage of fabrication of a product 100, in accordance with an embodiment of the present invention.

A substrate 110 can be selected from a group comprised of, for example, a silicon wafer, germanium, silicon-germanium alloy, carbon-doped silicon, carbon-doped silicon-germanium alloy, and compound (e.g. III-V and II-VI) semiconductor materials. The top surface of the substrate is cleaned, polished, or flattened by a CMP process.

FIG. 2 illustrates a diffusion barrier 120 that was epitaxially grown on the substrate 110, in accordance with an embodiment of the present invention. The diffusion barrier 120 is epitaxially grown one layer at a time on top of the substrate 110, after the substrate 110 has been cleaned. An ALD process can be utilized to epitaxially form the diffusion barrier one monolayer at a time. The material selected for the diffusion barrier 120 should have a lattice constant that is close to the lattice constant of the substrate 110, i.e. the diffusion barrier should have a lattice constant that is close to the lattice constant of Silicon. By epitaxially growing the diffusion barrier 120 one monolayer at a time, the growth stress can be reduced. The defects occurred by the mismatch of the lattice constants between the substrate 110 and that of the diffusion barrier 120 can be reduced by growing the diffusion barrier 120 one monolayer at a time. The diffusion barrier 120 can have a height (H)/thickness of about 1-3 nm. The diffusion barrier 120 can be comprised of an alloy, wherein the alloy is comprised of a deposited metal and a Si, or it can be a comprised of the deposited metal. The diffusion barrier 120 comprises a metal selected from a group consisting of: aluminum, cobalt, gallium, indium, lanthanum, molybdenum, niobium, rhenium, ruthenium, tin, tantalum, titanium, zinc, zirconium, and alloys thereof. The diffusion barrier 120 can be comprised of an alloy for example, CoSi₂, NbSi₂, TiSi₂, or other combinations based on the deposited metal forming a silicide with the substrate. The diffusion barrier 120 material should not have a melting point that is lower than the temperature required to form the layer 130 on top of the diffusion barrier 120.

FIG. 3 illustrates a layer 130 formed on the diffusion barrier 120, in accordance with an embodiment of the present invention. FIG. 4 illustrates the product 100 after the layer 130 and the diffusion barrier 120 were etched, in accordance with an embodiment of the present invention.

A layer 130 can be formed on top of the diffusion barrier 120. The layer 130 can be a metal, an alloy, a superconductor, an oxide, a nitride, for example, the layer can be Niobium. The layer 130 and the diffusion barrier 120 are etched to the desired component. The layer 130 and the diffusion barrier 120 can be etched utilizing conventional etching techniques to form the component. For example, the layer 130 can be formed into a niobium resonator on top of the diffusion barrier 120. For example, if the diffusion barrier 120 is a silicide, (for example, CoSi₂, NbSi₂, or TiSi₂) then forming layer 130 (for example, sputtering Nb on top of silicide diffusion barrier 120) should lead to a very low stress and near crystallographic perfect interface.

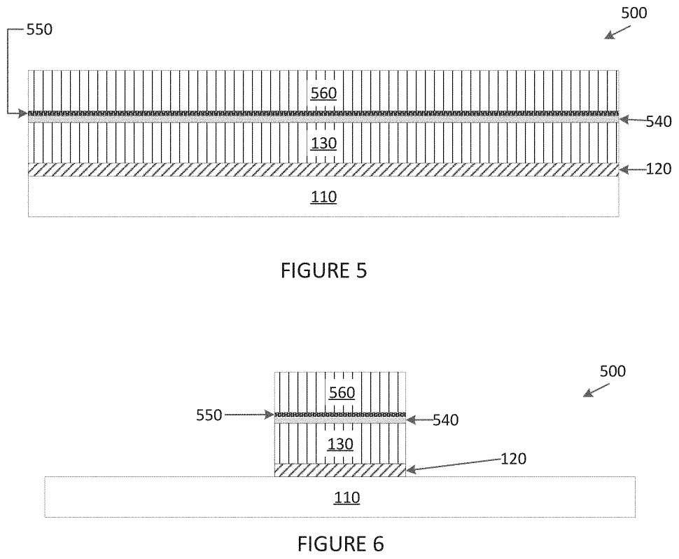

FIG. 5 illustrates a plurality of layers formed above the diffusion barrier 120, in accordance with an embodiment of the present invention. FIG. 6 illustrates the product 500 after the layer and the diffusion barrier were etched, in accordance with an embodiment of the present invention.

Layer 130 is formed on top of the diffusion barrier 120 and the layer 130 can act as a base layer for the product 500. A plurality of layers 540, 550, 560 can be formed on top of the layer 130 to form a multilayer product 500. The plurality of layers 120, 130, 540, 550, and 560 are etched to form the desired product 500. The product 500 can be for example a Josephson Junction comprising a tunnel barrier and a top conducing layer. The tunnel barrier can be comprised of a signal layer or it can be comprised of a plurality of layers. For example, the tunnel barrier can be comprised of an Aluminum layer 540 and an Aluminum Oxide layer 550. The top conducting layer can be comprised of a Niobium layer 560. The top conductive layer 560, the tunnel barrier layers 550, 540, layer 130 and the diffusion barrier 120 are etched to form the Josephson Junction.

While the invention has been shown and described with reference to certain exemplary embodiments thereof, it will be understood by those skilled in the art that various changes in form and details may be made therein without departing from the spirit and scope of the present invention as defined by the appended claims and their equivalents.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the one or more embodiment, the practical application or technical improvement over technologies found in the marketplace, or to enable others of ordinary skill in the art to understand the embodiments disclosed herein.

What is claimed is:

1. A method comprising:
cleaning the top surface of a silicon substrate;
forming a diffusion barrier by depositing a metal on top the top surface of the silicon substrate, wherein the diffusion barrier is formed one monolayer at a time, wherein the diffusion barrier will have a height of about 1 to 3 nm; and
forming a layer of crystalline Niobium on top of the diffusion barrier.

2. The method of claim 1, wherein the metal is selected from a group consisting of: aluminum, cobalt, gallium, indium, lanthanum, molybdenum, niobium, rhenium, ruthenium, tin, tantalum, titanium, zinc, zirconium, and alloys thereof.

3. The method of claim 1, wherein the diffusion barrier is a silicide alloy comprised of the deposited metal and the silicon wafer.

4. The method of claim 3, wherein the silicide alloy is selected from a group consisting of: CoSi₂, NbSi₂, TiSi₂.

5. A resonator comprising:
a silicon wafer;
a diffusion barrier formed on the surface of the silicon wafer, wherein the diffusion barrier by depositing a metal on top the top surface of the silicon substrate, wherein the diffusion barrier is formed one monolayer at a time, wherein the diffusion barrier will have a height of about 1 to 3 nm; and
a crystalline niobium resonator formed on top of the diffusion barrier.

6. A device comprising:
a silicon wafer;
a diffusion barrier formed on the surface of the silicon wafer, wherein the diffusion barrier by depositing a metal on top the top surface of the silicon substrate, wherein the diffusion barrier is formed one monolayer at a time, wherein the diffusion barrier will have a height of about 1 to 3 nm;
a first crystalline niobium layer formed on top of the diffusion barrier;
a tunnel barrier material formed on top of the first crystalline niobium layer; and
a second crystalline niobium layer formed on top of the tunnel barrier material.
